(19) United States
(12) Patent Application Publication
(10) Pub. No.: US 2003/0211711 A1
(43) Pub. Date: Nov. 13, 2003

(54) Wafer processing method and ion implantation apparatus

(76) Inventors: Hirofumi Seki, Hitachi (JP); Katsumi Tokiguchi, Mito (JP)

Correspondence Address: MATTINGLY, STANGER & MALUR, P.C., 1800 DIAGONAL ROAD, SUITE 370, ALEXANDRIA, VA, 22314, US

(21) Appl. No.: 10/397,187

(22) Filed: Mar. 27, 2003

(30) Foreign Application Priority Data
Mar. 28, 2002 (JP) 2002-90195

(51) Int. Cl. H01L 21/20; H01L 21/36

(52) U.S. Cl. 438/480

(57) ABSTRACT

The object of the present invention is to provide a wafer processing method for forming ultra thin SOI and thick BOX films by implanting oxygen ion beams with different energy levels in the same silicon wafer at a low accelerating voltage. To solve this subject, the oxygen ion beams with different energy levels are irradiated in the same wafer. According to the configuration mentioned above, the SIMOX wafer including the SOI and BOX films, either of which has the same thickness, can be manufactured at a lower accelerating voltage, half of the conventional one, providing economical implantation apparatus.

### BACKGROUND OF THE INVENTION

1. Field of the Invention

The present invention relates to a wafer processing method and in particular to the wafer processing method suitable for forming an ultra thin film silicon wafer on an insulator (hereafter, simply referred to as a SOI) with a thickness of 100 nm or less, which is deposited on a buried oxide film layer.

2. Discussion of the Background

Recently, to fabricate a fast semiconductor chip, an ultra thin SOI film is used (NIKKEI MICRO DEVICES, February 2002, p76-88: hereafter, simply referred to as the Document 1) According to ITRS (INTERNATIONAL TECHNOLOGY ROADMAP FOR SEMICONDUCTORS 2001 EDITION, FRONT END PROCESS, hereafter, simply referred to as the Document 2), the SOI film is made more and more thinner as the chip has been increasingly miniaturized. One of ultra thin SOI film manufacturing methods is a silicon implantation by oxygen (SIMOX) method.

One of the conventional SIMOX methods is described in, for example, “High-Quality Low-Dose SIMOX Wafers”, by Sadao NAKASHIMA, IEICE TRANS. ELECTRON., VOL. E80-C, NO.3 MARCH 1997, pp. 364-369: hereafter, simply referred to as the Document 3). According to the Document 3, the manufacturing process starts with the irradiation of oxygen ion beams in a silicon wafer. Then, the wafer is heat treaded at a high temperature (hereafter, simply referred to as annealing) in an argon atmosphere to form a buried oxide film layer (hereafter, simply referred to as a BOX). Finally, the wafer undergoes the internal thermal oxidation process (hereafter, simply referred to as ITOX) not only to make the SOI film thinner through the oxidation reaction but also to improve the quality of the SOI and BOX films. This enables ultra thin SOT films to be deposited.

According to U.S. Pat. No. 5,080,730 (hereafter, simply referred to as the Document 4), oxygen ions are implanted in the wafer with varying energy to compensate for any peel off of a Si surface layer during oxygen ion implantation.

According to JP-A No. 289552/2002 (hereafter, simply referred to as the Document 5), to form the BOX layer, these steps are taken: oxygen ions are implanted in the wafer, the ion-implanted wafer is annealed, the energy level of oxygen ions is changed or a silicon layer in the wafer surface is removed to implant oxygen ions on the underside of the BOX layer, and the wafer is re-annealed to make the BOX layer thicker.

According to JP-A No. 249323/1992 (hereafter, simply referred to as the Document 6), in a high-dose SIMOX process, oxygen ion beams are implanted with varying energy and the ion-implanted wafer is re-annealed so that after the oxygen ions are implanted and the ion-implanted wafer is annealed to form the BOX layer, a density peak may appear on the surface of the BOX layer.

According to JP-A No. 201975/1995 (hereafter, simply referred to as the Document 7), the implantation depth and dose amount of oxygen ions are continuously or stepwise varied so that the distribution of oxygen atom concentrations may have a single maximum value, where the maximum value is any in a range from 1.0×10²²/cm² (including) to 4.0×10²²/cm² (including).

### SUMMARY OF THE INVENTION

The SIMOX method introduced in the Documents 1-3, has the following problems. In other words, to achieve a combination of the ultra thin SOI and thick BOX films by applying energy generated from oxygen ion implantation, it is required that an accelerating voltage be increased and the wafer undergo the ITOX process for a longer time period. This causes a problem of larger manufacturing equipment and higher cost.

For example, if the silicon wafer, on which oxygen ions with a energy level of 180 keV were implanted at a dose amount of 3.7×10¹⁷ cm⁻², is heat-treated at a temperature of 1350° C. for four hours in the atmosphere of a mixture of 1% oxygen and 99% argon, the SOI film with a thickness of 335 nm and the BOX layer with a thickness of 87 nm would be formed. As shown in FIG. 9, when the resultant SOI and BOX film layers undergo the ITOX process for a longer time period, the SOI film is made thinner while the BOX film thicker. For example, if the thickness of the SOI layer is reduced to 20 nm, that of the BOX layer is increased to 130 nm. Too long ITOX process limits the ITOX process for fabricating the thick BOX film because the SIO layer disappears.

An increase in ion energy level allows oxygen ions to be implanted at a deeper position, resulting in a thicker SOI layer after heat treatment. This means that the BOX layer is formed at the deeper position further away from the silicon surface. Thus, the ITOX process can be applied for a longer time period compared with conventional processes, producing the thicker BOX layer.

For example, if the silicon wafer, on which oxygen ions with an energy level of 240 keV were implanted at a dose amount of 4×10¹⁷ cm⁻², is heat-treated at a high temperature, the SOI layer with a thickness of 450 nm and the BOX layer with a thickness of 90 nm would be formed. If the thickness of the SOI layer is reduced to 20 nm, that of the BOX layer is increased to 160 nm.

Thus, the methods in the publications above mentioned require the implantation of hydrogen ions with a higher level of energy to make the BOX layer thicker. This means that in this case, since the voltage for accelerating the ion beam is high, a larger insulation distance must be considered, requiring a larger implantation apparatus. Alternately, one of the methods for enhancing the throughput of wafer fabrication is to make an implantation current larger. Making the implantation current larger with the acceleration voltage kept constant requires the implantation of ions with a higher level of energy. This may induce thermal deformation, distortion, and even a crack on the wafer.

As described above, assuming that the wafer with the ultra thin SOI/thick BOX films, either of which has uniform thickness, can be produced, the size of a low-energy implantation apparatus may be reduced because the insulation distances of individual parts may be shortened. If implantation power as high as that of a high-energy implantation apparatus can be supplied, the implantation current may be made larger. This allows a given dose amount of ions to be implanted for a short time, improving the throughput.

For this reason, a low-voltage implantation apparatus is economically superior to a high-voltage implantation apparatus. The method mentioned above, however, has such a problem that when implantation energy is made smaller, the BOX layer is made thinner, leading to inability to form the BOX layer with a given thickness.

According to the prior art disclosed in the Document 4, a continuous buried oxide film layer can be formed but not made thicker. According to the prior art of the Document 5, the throughput of wafer production decreases, increasing its cost considerably because oxygen ion implantation and annealing are repeated and an additional step, wafer surface removal, is included. In addition, such another problem may occur that since ions are implanted through the BOX layer, fixed charges remain left on the BOX layer.

Similarly, according to the Document 6, the throughput decreases because oxygen ion implantation and annealing are repeated and the fixed charges tend to remain left because about half of oxygen ions enter into the BOX layer. Such another problem may occur that because of a high-dose SIMOX process, the oxygen ion dose amount is large while the throughput is small.

According to the Document 7, a low-dose amount of ions, at which no BOX layer is formed by single implantation, are implanted several times with varying energy to accumulate ions up to the given dose amount, at which a BOX layer can be formed. In this case, however, since on a distribution of defects generated by single implantation, oxygen ions are also accumulated with varying depth, a distribution of implanted ions overlaps extensively the distribution of defects. For this reason, oxygen ions implanted during heat treatment are supplemented in the distribution of defects and a diffusion coefficient of oxygen atoms into silicon reduces substantially. As a result, a large number of dangling bonds, or unsaturated bonds, such as Si—O remain left, making it difficult to form a continuous SiO₂ layer from an aspect of chemical composition. Accordingly, such a problem that the withstand voltage of the BOX layer is inferior to that of a thermally-oxidized film.

The present invention has been made in light of the point mentioned above and its object is to provide the wafer processing method, which allows a combination of the ultra thin SOI and thick BOX films with no time-consuming longer ITOX process by increasing the acceleration voltage, or with no larger implantation apparatus/increased cost.

To solve the problems mentioned above, in the present invention, oxygen ions with different energy levels are implanted into the same wafer. Since this characteristic of the present invention allows the distribution of the ions implanted into the silicon wafer, a thick BOX layer may be formed even at a low accelerating voltage.

### BRIEF DESCRIPTION OF THE DRAWINGS

FIG. 1 is a process view showing a wafer processing method of the present invention.

FIG. 2 is a characteristic view showing the dependency of the implantation depth of oxygen ions on the accelerating voltage.

FIG. 3 is a characteristic view showing the relationship between the distribution of oxygen ions implanted into the silicon wafer and the accelerating voltage.

FIG. 4 is a characteristic view showing the relationship between the time required for ITOX in the oxygen atmosphere and the reduction in silicon on insulator (SOI) film thickness.

FIG. 5 is a characteristic view showing the relationship between the time required for ITOX in the oxygen atmosphere and the increase in buried oxide (BOX) film thickness.

FIG. 6 is a characteristic view showing the relationship between the dose amount and the accelerating voltage.

FIG. 7 is the second embodiment of the present invention.

FIG. 8 is a schematic view showing the oxygen ion implantation apparatus according to the present invention.

FIG. 9 is a view showing the process for making the SOI layer thinner by ITOX.

FIG. 10 is a view explaining the processing method according to the embodiment of the present invention.

FIG. 11(a) is a view showing the distribution of implanted oxygen ions and the distribution of defects.

FIG. 11(b) is a view showing the distribution of oxygen ions and the distribution of defects disclosed in JP-A No. 201975/1995.

FIG. 12 is a view showing the relationship between difference in energy and energy of implanted ions.

### DETAILED DESCRIPTION OF THE PREFERRED EMBODIMENTS

Now, referring to the drawings attached, the embodiments of the present invention are explained. FIG. 8 is a view explaining the overview of an oxygen ion implantation apparatus according to the present invention.

Referring to FIG. 8, the oxygen ion planter is comprised mainly of an ion source, a mass separation magnet, a post-deflection accelerating tube, a quadrupole lens, a deflecting magnet, and an implanting chamber. A wafer holder for supporting the wafer is disposed in the implanting chamber, on which the wafer is mounted. The implanting chamber is kept under the vacuum condition during implantation. During implantation, the wafer either rotates or rotates and pendularly moves and oxygen ion beams are uniformly irradiated on it. Note that the post-deflection accelerating tube is not necessarily required.

Secondly, the operational principle and functionality of the oxygen ion implantation apparatus according to the present invention are explained. A coil is wound around the ion source to generate an electron cyclotron resonance magnetic field and exhausted by a vacuum pump. When an oxygen gas is introduced and then a microwave is irradiated, oxygen plasma is produced.

The oxygen ions are accelerated to several tens kiloelectron volts to one hundred and several tens kiloelectron volts by a drawing electrode and emit from the ion source. Since the oxygen ion beams emitted from the ion source contain univalent oxygen ions, oxygen molecular ions, bivalent oxygen ions, and others, the mass separation magnet is used to separate the univalent oxygen ion beams only. The separated univalent oxygen ion beams are further accelerated to a higher energy level by the post-deflection accelerating tube and then shaped by the quadrupole lens.

After then, to remove ions generated in the post-deflection accelerating tube, the beam orbit is deflected by the deflecting magnet to direct to the implanting chamber. In the implanting chamber, (not shown in the figure), to make the distribution of oxygen ions implanted in the wafer uniform on the wafer surface, the holder for fixing the wafer is rotated and pendularly moved. By the way, the oxygen ion beam scan may be performed instead of the holder being pendularly moved.

The implantation apparatus according to the preferred embodiment provides a control unit (not shown in the figure) for controlling applied voltage and current supplied to each of the elements mentioned above. The control unit has also a storage (not shown in the figure), which has a program for controlling the accelerating means and the movement of the wafer holder so that ions may be implanted following the steps described below.

Alternately, the control unit may be configured so that the energy level of the oxygen ion may be automatically selected by entering the desired thickness of SOI and BOX layers. This option can be achieved by preparing such a program that the omitted parameters are determined based on the desired parameters entered in the fields for the implantation depth and variation of the ion energy level, the SOI film thickness, and the variation of the BOX film thickness, which have been predetermined.

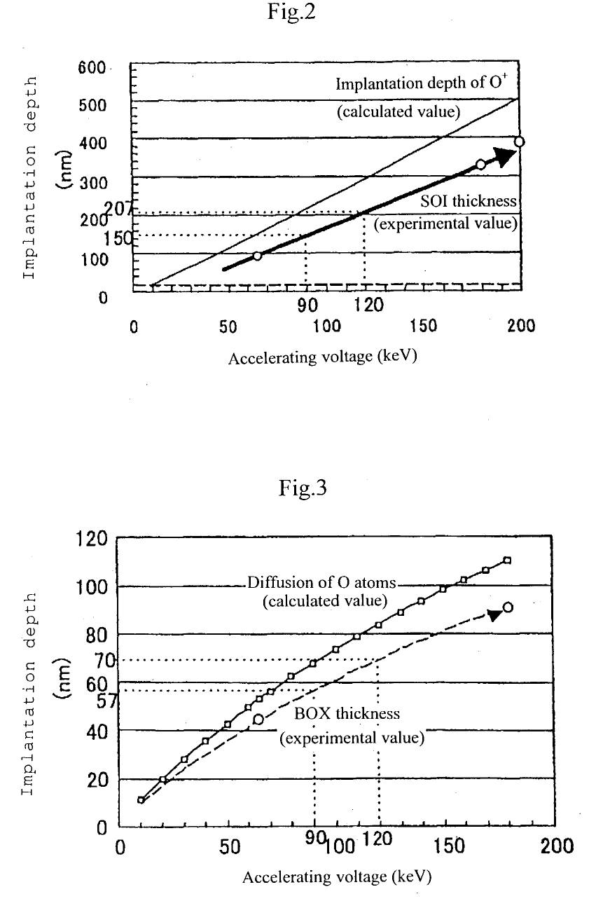

FIG. 2 shows the dependency of the implantation depth of oxygen ions on the accelerating voltage obtained from calculations. In FIG. 2, the thickness of the SOI layer obtained after it is annealed at 1350° C. for four hours in the argon atmosphere is indicated by a circle (0).

As known from the figure, as the accelerating voltage increases, oxygen ions are implanted more deeply, making the SOI film obtained after annealing thicker. For this reason, it is understood that to form the thick SOI layer, the accelerating voltage must be increased.

Then, referring to FIG. 3, the relationship between the distribution of oxygen ions implanted the silicon wafer and the accelerating voltage are shown. As known from the figure, since the diffusion of oxygen ions and the thickness of the BOX film after annealing correspond on another, the accelerating voltage must be increased to for the thick BOX film.

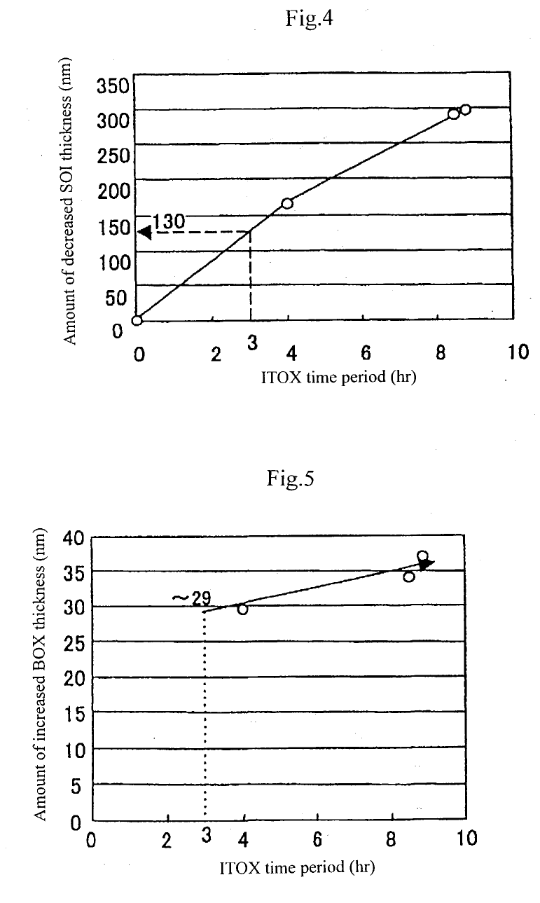

FIGS. 4 and 5 show the amounts of decreased ITOX time period and of increased SOT film thickness. This means that The SOI film is made thinner while the BOX film is made thicker. To ensure the quality of the BOX film, it must be made thicker. Since, however, the long ITOX process causes the SOT film to disappear, it is required that oxygen ions with a higher energy level be more deeply implanted to form the thick SOT film in order to make the BOX film thicker.

Thus, with respect to the conventional prior art, the accelerating voltage must be increased to make the BOX layer in order to improve its reliability. This leads to increased cost for the implantation apparatus. To make the cost for the implantation apparatus lower, it is vital to decrease the accelerating voltage. On the other hand, if the implantation voltage is decreased, the oxygen ions are less deeply implanted and the BOX film cannot be made thicker, resulting in impossible improvement of the reliability of the BOX layer.

To solve this problem, the method according to the invention implants the oxygen ions with different energy levels in the same wafer. This allows the distribution of oxygen ions implanted in the silicon wafer to be diffused so that the buried oxide film layer may be bonded, resulting in the thick BOX layer even at the low accelerating voltage.

In particular, the present invention can be characterized by that the BOX layers formed by the implanted oxygen ions with different energy levels are overlapped and that the energy levels and dose amounts are selected so that the separation distance may be within 10% of the BOX layer.

Now, the characteristics of the prevent invention mentioned above is described below.

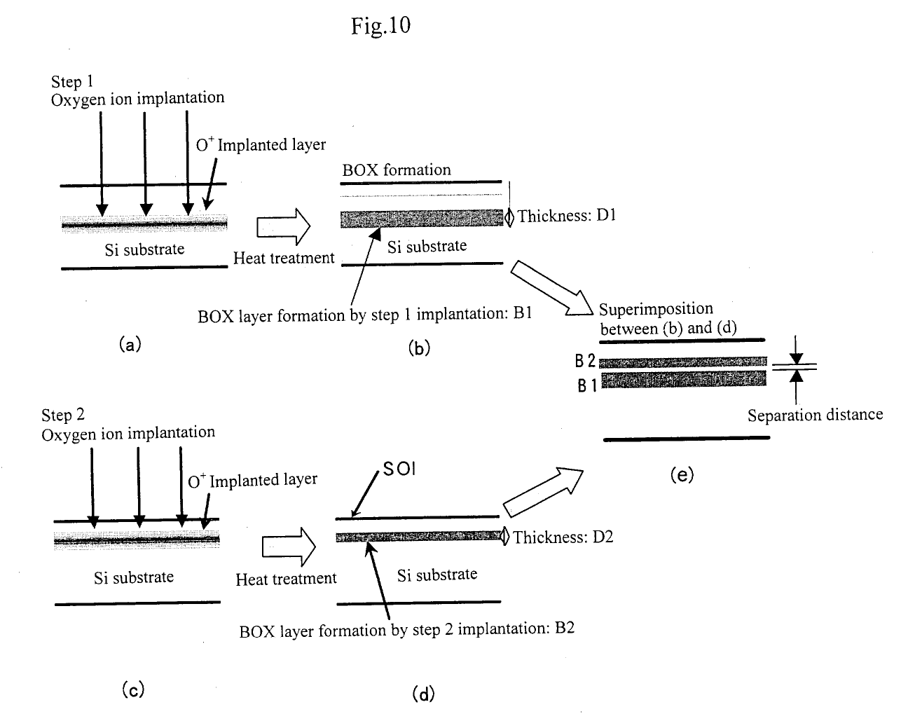

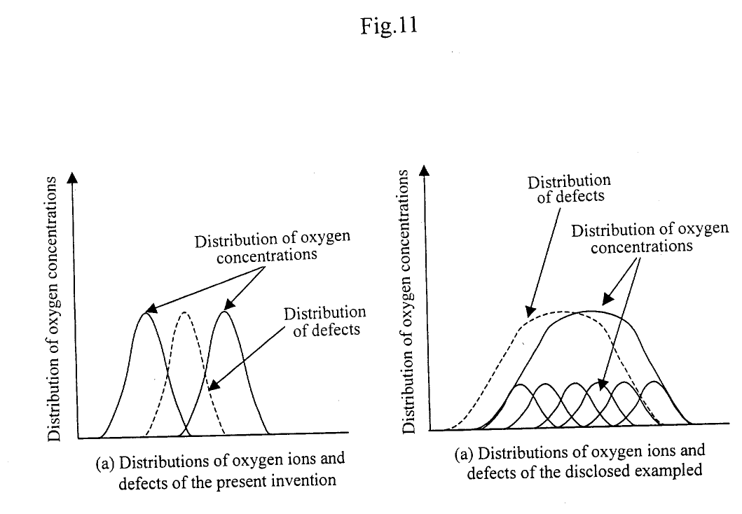

Referring to FIG. 10, a two-step implantation is given as an example for clarification. Note that this explanation may be applicable to the three-step or more implantation. As shown in FIGS. 10(a) and 10(b), the BOX layer formed after only the first implantation and then heat treatment are performed is referred to as B₁ and the thickness of B1 as D1. As shown in FIGS. 10(c) and 10(d), the BOX layer formed after only the second implantation and then heat treatment are performed is referred to as B2 and the thickness of B2 as D2.

FIG. 10(e) clearly shows the physical relationship between B1 and B2 described in FIGS. 10(b) and 10(d) by overlapping. If the separation distance between B1 and B2 is equal to or less than about 10% of the D1 or D2, whichever being smaller or the superimposed distance between B1 and B2 is equal to or less than about 10% of D1 or D2, whichever being smaller, the continuous BOX layer can be formed by performing the heat treatment after two-step implantation.

On the contrary, if they are out of the predefined range, no continuous BOX layer is formed. If the separation distance between B1 and B2 exceeds about 10% of D1 or D2, whichever being smaller, a two-layer BOX layer is formed and if the superimposed distance between B1 and B2 exceeds about 10% of D1 or D2, whichever being smaller, a silicon island may be contained in the BOX layer.

Additionally, unlike the method described in the Patent Document 4, in this method since the overlapped portion between the distribution of defects and the distribution of implanted oxygen ions is small, the oxygen ions are difficult to be bonded to the defectives. For this reason, the BOX layer with a withstand voltage characteristic, which is closest to the thermal oxide film, can be formed.

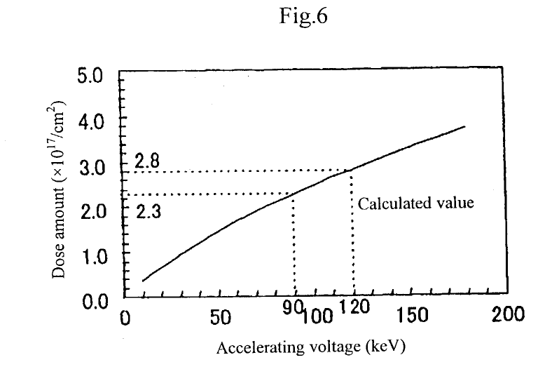

Now, the method according to the present invention is described giving an actual example. Suppose to find the conditions for forming SOI with a SOI thickness of about 20 nm and a BOX thickness of about 160 nm. Base on the experiences accumulated so far, when the SOI thickness is reduced by 130 nm or more by ITOX, the high-quality SOI and BOX films can be obtained. Since the time required for the ITOX process is about 3 hours as shown in FIG. 4 and the amount of an increased BOX film is about 29 nm as shown in FIG. 5, the BOX film thickness must be about 131 nm and the SOI film thickness about 150 nm. The dose amount can be determined based on FIG. 6. To form these BOX and SOI layers, the oxygen ions may be implanted in the wafer under the conditions, an accelerating voltage of 90 keV and a dose amount of 2.3×10¹⁷ cm⁻² in the step 1 and under the conditions, an accelerating voltage of 120 keV and a dose amount of 2.8×10¹⁷ cm⁻² in the step 2.

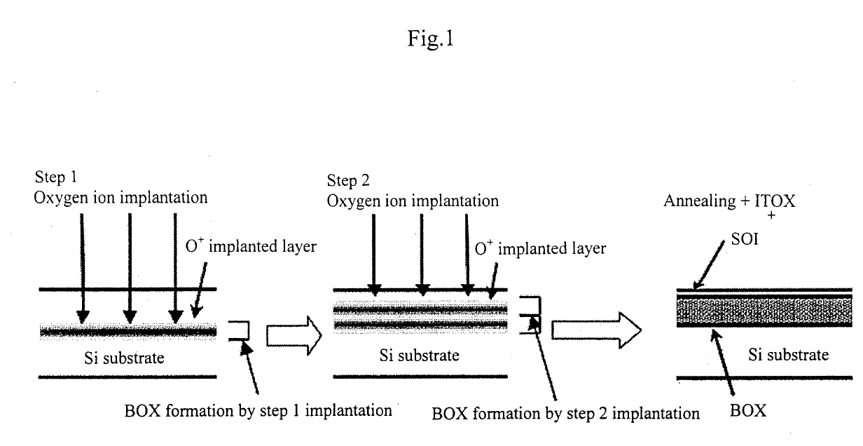

The process mentioned above is described below. As known from FIGS. 1 and 2, the SOI film with a thickness of 150 nm and the BOX film with a thickness of 57 nm are obtained in the step 1. Since in the step 2, the SOI film with a thickness of 207 nm and the BOX film with a thickness of 70 nm are obtained, the BOX layer can be extended on the underside of the BOX film formed in the step 1. This means that the thickness of the BOX layer is 127 nm (57+70=127). Since the BOX layer is made further thicker by 29 nm after ITOX, the total thickness of the BOX layer is 156 nm (127+29=156).

Thus, the application of the steps 1 and 2 and ITOX provides the SOI layer with a thickness of 20 nm and the BOX layer with a thickness of about 160 nm. If a further thicker BOX layer is required, the accelerating voltage may be somewhat increased in both the steps 1 and 2.

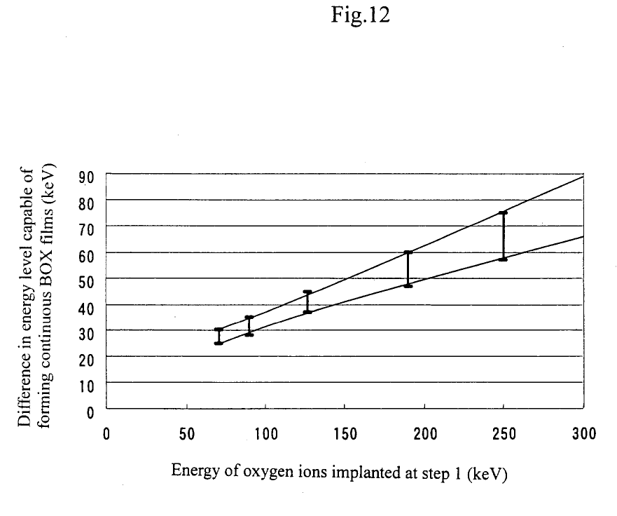

As known from this example, the separation distance and superimposed distance between the BOX layer formed by ion implantation in the step 1 and the BOX layer formed in the step 2 may be represented by difference in energy level of implanted ions. Now, the process is described below giving an example of the step 2 implantation. A lower level of oxygen ions is indicated on the horizontal axis while the continuous BOX layer forms on the vertical axis. The differences between the higher and lower energy levels can be represented as shown FIG. 12.

Where, the widths in the vertical axis direction shown in FIG. 12 indicate the differences in energy level depending on the dose amount. This means that since D1 and D2 are small if oxygen ions are implanted at the lower limit of the dose window, the difference in energy level must be enlarged. On the contrary, since D1 and D2 are large if they are implanted at the upper limit of the dose window, the difference in energy level must be narrowed.

To achieve surface roughness required for manufacturing LSI, a certain level of ITOX is necessary. Empirically, it is clear that average roughness of 0.7 nm or less cannot be achieved on the 10 μm×10 μm area of the SOI layer surface unless the thickness of SOI layer is reduced by 100 nm or more by the ITOX process. As known from FIG. 2, the lower limit of the energy level of implanted oxygen ions is 70 keV. In FIG. 12, the lower limit of the difference in energy level is 25 keV. For this reason, the roughness of the SOI layer is not suitable for manufacturing LSIs assuming that the continuous BOX layer is formed with the difference in energy level lower than the limit. The further preferred conditions are the lower energy level is 90 keV, and the corresponding difference in energy level is 30 keV. Although the difference in energy level enlarges as the energy level of implanted ions increases, since the upper limit of the difference in energy level is 90 keV because the energy level of implanted oxygen ions is equal to or less than 300 keV for a large current oxygen ion implantation apparatus, which may be generally configured. In this case, the difference of energy level is 70 keV because the energy level of the ion implantation apparatus currently available is 240 keV.

As mentioned above, to implant successfully the oxygen ions with the energy level of 120/90 keV, the accelerating voltage must be increased. Specifically, 220 keV of accelerating voltage and the long ITOX process are required. When the oxygen ions are implanted in the wafer at the accelerating voltage of 220 keV, the SOI with a thickness of 427 nm and the BOX with a thickness of 104 nm are obtained. After the ITOX process is performed on the wafer for 12 hours and 50 minutes, the thickness of the SOI layer is reduced to 20 nm while that of the BOX layer is increased to about 160 nm.

Thus, the use of two accelerating voltages allows the accelerating voltage to be considerably decreased. Although in this example, two accelerating voltages are used, three or more voltages may be considered. Note that if the voltages are too frequently changed, the operational procedure becomes complicated.

Accordingly, the BOX film can be made thicker at a low accelerating voltage by determining the energy level and dose amount the oxygen ions with different energy levels. In the above example, the BOX layer with a thickness of 160 nm is given. By changing the energy level or performing the three or more steps of implantation, the thickness of the BOX layer can be increased to 200 nm or more. This example is described below.

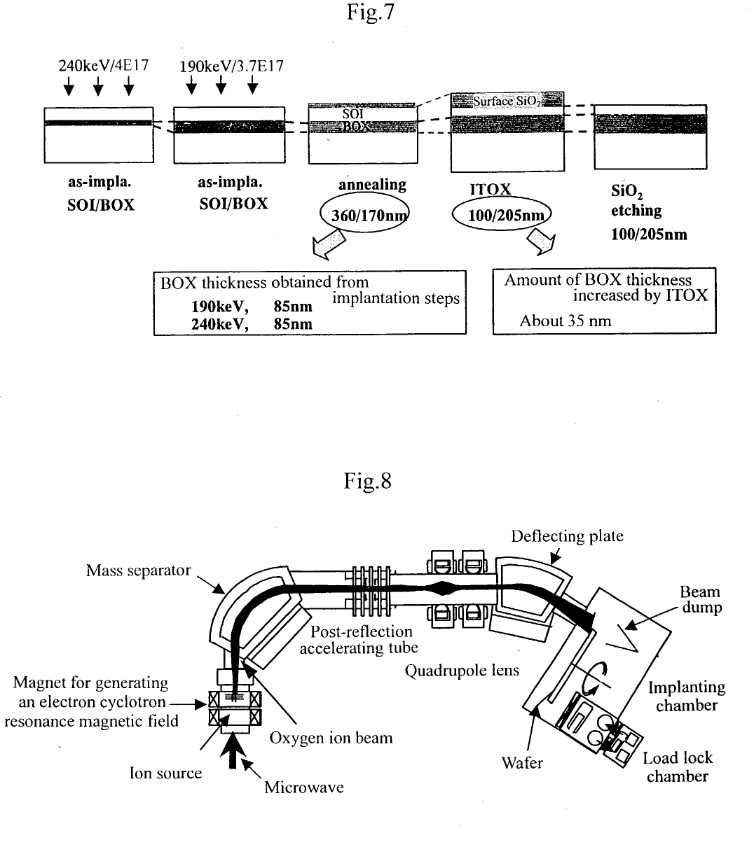

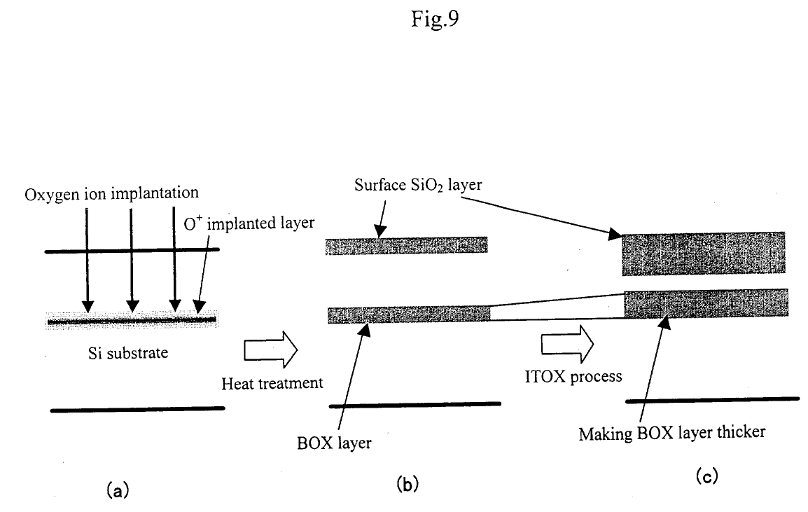

The second embodiment relates to the method for increasing the thickness of the BOX film to about 205 nm. In this case, the conditions as shown in FIG. 7 can be obtained by making a discussion in the same manner as that of the first embodiment.

This means that the step 1 implantation is performed under the conditions, an energy level of 240 keV and a dose amount of 4×10¹⁷/cm². When the oxygen ions are implanted under theses conditions, the BOX layer with a thickness of 85 nm is formed 445 nm far from the silicon surface after heat treat treatment.

Then the ions are implanted under the conditions, an energy level of 190 keV and a dose amount of 3.7×10¹⁷/cm². When the oxygen ions are implanted under theses conditions, the BOX layer with a thickness of 85 nm is formed at a depth of 360 nm, directly above the BOX film after heat treatment. By performing these two steps and then heat treatment at a temperature of 1350° C. for four hours, the SOI layer with a thickness of 360 nm and the BOX layer with a thickness of 170 nm are formed in the atmosphere containing a gas mixture of argon (about 10 L/min.) and oxygen (about 0.1 L/min).

As known from FIG. 4, after the ITOX process is performed for about 7 hours, the thickness of the SOI layer is reduced by 260 nm. Since the amount of increased BOX thickness is about 35 nm, the BOX layer with a thickness of about 205 nm after ITOX.

To implant the oxygen ions with an energy level of 240/190 keV in the step 1, the energy level of the oxygen ions must be increased. Specifically, the energy level of 350 keV and a long ITOX process over 20 hours are required.

As known from the two embodiments mentioned above, by decreasing the energy level of the oxygen ions, the difference in energy level between oxygen ions to be implanted is also reduced.

The 3 or more step of implantation may be performed in the same manner. For example, by performing the step 3 implantation under the conditions, an accelerating energy of 155 keV and a dose amount of 3.0×10¹⁷/cm⁻², in addition to the steps in the two embodiments, the SOI layer with a thickness of 281 nm and the SOI layer with a thickness of about 249 nm can be formed.

In the method for implanting oxygen ions mentioned above, for example, multiple ion beams with different energy levels may be irradiated in the same wafer at the same time. For example, referring to FIG. 8, single beam is irradiated in the one of multiple wafers supported by the wafer holder, through another beam may be irradiated in another wafer. With the electric potential of the wafer varied with time, the energy level of oxygen ions, when implanted, may be effectively changed. It is not necessarily required that the oxygen ion beam with a higher energy level be implanted first.

The method and implantation apparatus of the present invention can meet the requirements for forming the thick BOX film by the multi-implantation. According to the present invention, the ultra thin SOI film with a thickness of 20 nm or less and the thick BOX film with 150 nm or more can be easily and stably formed.

Thus, according to the present invention, the SIMOX method can be applied at a low accelerating voltage, providing economical implantation apparatus.

What is claimed is:

1. A wafer processing method, in which an oxide film is formed in a silicon wafer by performing heat treatment after oxygen ions are implanted in a silicon wafer comprising:
a step for implanting first oxygen ions with an energy level less than 120 keV and second oxygen ions with an energy level of ranging from 120 keV (including) to 180 keV (including) in a silicon wafer.

2. A wafer processing method defined in claim 1, wherein the first oxygen ions and the second oxygen ions are implanted in a same wafer.

3. A wafer processing method defined in claim 1, wherein the first oxygen ions and the second oxygen ions are implanted at the same time.

4. A wafer processing method, in which the oxygen ions are implanted in the silicon wafer and the silicon wafer with the oxygen ions implanted is heat treated to form a buried oxide film layer in the silicon wafer, and then the heat treated at a high temperature silicon wafer is further heat treated in an oxygen atmosphere at a high temperature to make the silicon layer on the buried oxide film layer thinner and to make the buried film layer thicker comprising:
a step for implanting oxygen ions with at least two different energy levels to form the buried oxide film layers with different depths, the oxygen ions with at least the two different energy levels are implanted so that the buried oxide film layers may be bonded together to form the oxide film layer with a thickness of 150 nm or more and the silicon layer with a thickness of 20 nm or less may be formed; and
a step for heat treating the silicon wafer at a high temperature in the argon atmosphere and the oxygen atmosphere.

5. A wafer processing method defined in claim 4, wherein the silicon wafer is heat treated at a high temperature in the oxygen atmosphere so that the silicon layer may be reduced by 130 nm or more.

6. A wafer processing method defined in claim 5, wherein the buried oxide film layer is formed at a depth where the oxide film layer with a thickness of 150 nm or more is formed by heat treatment at a high temperature when the silicon layer is reduced by 130 nm or more.

7. A wafer processing method defined in claim 4, wherein the silicon wafer has the oxide film layer and the silicon layer.

8. A wafer processing method, in which after the oxygen ions are implanted in it, a silicon wafer is heat treated at a high temperature to form the buried oxide film layer comprising:
a step for implanting the oxygen ions with at least two different energy levels in the silicon wafer to form the buried oxide film layer, the two different energy levels adjust the conditions for ion implantation so that the superimposed distance and the separation distance among the curried oxide film layers may be 10% or less of the thickness of the buried oxide film layer.

9. A wafer processing method defined in claim 8, wherein oxygen ions with at least two different energy levels are implanted in the same silicon wafer.

10. A wafer processing method defined in claim 8, wherein the oxygen ions with at least two different energy levels are implanted in the silicon wafer at the same time.

11. A wafer processing method defined in claim 8, wherein one of the two energy levels is less than 120 keV and the other is any in a range from 120 keV (including) to 180 keV (including).

12. A wafer processing method defined in claim 8, wherein one of the two energy levels is any in a range from 150 keV (including) to 190 keV (including) and the other is any in a range from 190 keV (including) to 240 keV (including).

13. A wafer processing method, in which after the oxygen ions are implanted in it, a silicon wafer is heat treated at a high temperature to form the buried oxide film layer comprising:
a step for implanting the oxygen ions with at least two different energy levels in the silicon wafer to form the buried oxide film layer, wherein the difference between the two different energy levels is any in a range from 30 keV (including) to 70 keV (including).

14. A wafer processing method defined in claim 13, wherein the energy level of the oxygen ions, which reach the silicon wafer, are adjusted by controlling the electric potential of the silicon wafer.

15. A wafer processing method, in which the oxygen ions are implanted in the silicon wafer and the silicon wafer with the oxygen ions implanted is heat treated at a high temperature to form a buried oxide film layer in the silicon wafer, and then the heat treated at a high temperature silicon wafer is further heat treated in an oxygen atmosphere at a high temperature to make the silicon layer on the buried oxide film layer thinner and to make the buried film layer thicker comprising:
a step for implanting the first oxygen ions so that the buried oxide film layer may be formed at the depth of 130 nm or more; and
a step for implanting the second oxygen ions in the silicon wafer so that the oxide film with a given thickness or more (total thickness of the first and second oxygen ion layers) may be formed when the silicon layer is reduced by 130 nm or more.

16. An ion implantation apparatus comprising:
a mass separation part, at which the oxygen ions are extracted from the ions drawn from the ion source;
a holder for supporting a sample, in which the oxygen ions extracted at the mass separation part;
a implanting chamber including the holder, in which a vacuum atmosphere remains left; and
a control unit for controlling the energy levels of the oxygen ions, which reach the sample, wherein the control unit controls the energy levels, one of which is 90 keV or more and the other is 120 keV or more, so that the oxygen ions with two different energy levels may be implanted in the same sample supported by the holder.
